(19) United States
(12) Patent Application Publication
(10) Pub. No.: US 2022/0189785 A1
(43) Pub. Date: Jun. 16, 2022

(54) METHOD FOR MANUFACTURING SEMICONDUCTOR DEVICE AND SUBSTRATE PROCESSING APPARATUS

(71) Applicant: Tokyo Electron Limited, Tokyo (JP)

(72) Inventors: Yutaka MOTOYAMA, Yamanashi (JP); Hiroaki IKEGAWA, Yamanashi (JP); Satoshi TAKAGI, Yamanashi (JP); Daisuke SUZUKI, Yamanashi (JP)

(21) Appl. No.: 17/456,609

(22) Filed: Nov. 26, 2021

(30) Foreign Application Priority Data
Dec. 16, 2020 (JP) 2020-208800

(51) Int. Cl. H01L 21/3205; H01L 21/311; C23C 16/24

(52) U.S. Cl. CPC H01L 21/32055; H01L 21/02645; C23C 16/24; H01L 21/31116

(57) ABSTRACT

A method for manufacturing a semiconductor device is provided. In the method, an amorphous silicon film is deposited in a recess provided in a surface of a substrate by supplying a silicon-containing gas to the substrate. The amorphous silicon film is etched by supplying an etching gas to the substrate so as to leave the amorphous silicon film on a bottom of the recess. A silicon film is deposited on the amorphous silicon film by supplying dichlorosilane to the substrate.

### CROSS-REFERENCE TO RELATED APPLICATION

The present application is based on and claims priority to Japanese Priority Application No. 2020-208800 filed on Dec. 16, 2020, the entire contents of which are hereby incorporated herein by reference.

### BACKGROUND OF THE INVENTION

### 1. Field of the Invention

The present disclosure relates to a method for manufacturing a semiconductor device and a substrate processing device.

### 2. Description of the Related Art

Japanese Laid-Open Patent Application Publication No. 2017-228580 discloses a method for manufacturing a semiconductor device for filling a recess with a silicon film by repeating a cycle of supplying a film deposition gas containing silicon to a workpiece including the recess formed in a surface to form a silicon film in the recess, supplying a process gas including a halogen gas for etching a silicon film and a roughness inhibiting gas for inhibiting the roughness of the surface of the silicon film after etching by the halogen gas, supplying thermal energy to the process gas to activate the process gas, and expanding the opening width of the recess. Such a filling method is referred to as a DED (Deposition Etch Deposition) process because the method repeats deposition and etching.

### SUMMARY OF THE INVENTION

In an embodiment, the present disclosure provides a method for manufacturing a semiconductor device and a substrate processing apparatus in which a recess is filled with a silicon film without generating a void by bottom-up film deposition without repeating a DED process.

According to one embodiment of the present disclosure, there is provided a method for manufacturing a semiconductor device. In the method, an amorphous silicon film is deposited in a recess provided in a surface of a substrate by supplying a silicon-containing gas to the substrate. The amorphous silicon film is etched by supplying an etching gas to the substrate so as to leave the amorphous silicon film on a bottom of the recess. A silicon film is deposited on the amorphous silicon film by supplying dichlorosilane to the substrate.

### BRIEF DESCRIPTION OF THE DRAWINGS

FIG. 1 is a substrate processing apparatus according to an embodiment of the present disclosure;

FIG. 2 is a diagram illustrating an example of a shape of a recess formed in a surface of a wafer;

FIGS. 3A to 3D are diagrams illustrating an example of a typical conventional DED process;

FIGS. 4A to 4G are diagrams illustrating a conventional selective growth method improved relative to the method of FIGS. 3A to 3D;

FIGS. 5A to 5G are diagrams based on a TEM image corresponding to FIGS. 4A to 4G;

FIGS. 6A to 6D are diagrams illustrating an example of a method for manufacturing a semiconductor device according to an embodiment of the present disclosure;

FIGS. 7A to 7D are diagrams based on a TEM image corresponding to FIG. 6 for explaining an example of a method for manufacturing a semiconductor device according to an embodiment of the present disclosure;

FIG. 8 is a diagram based on a TEM image showing a result of performing a method for manufacturing a semiconductor device according to the present embodiment;

FIGS. 9A and 9B are diagrams showing a problem of a conventional method for manufacturing a semiconductor device; and

FIG. 10 is a diagram comparing a state of fins of a semiconductor device manufactured by a method for manufacturing a semiconductor device according to the present embodiment with the conventional DED process described in FIGS. 4 and 5.

### DETAILED DESCRIPTION OF THE PREFERRED EMBODIMENTS

Hereinafter, embodiments for carrying out the present invention will be described with reference to the drawings.

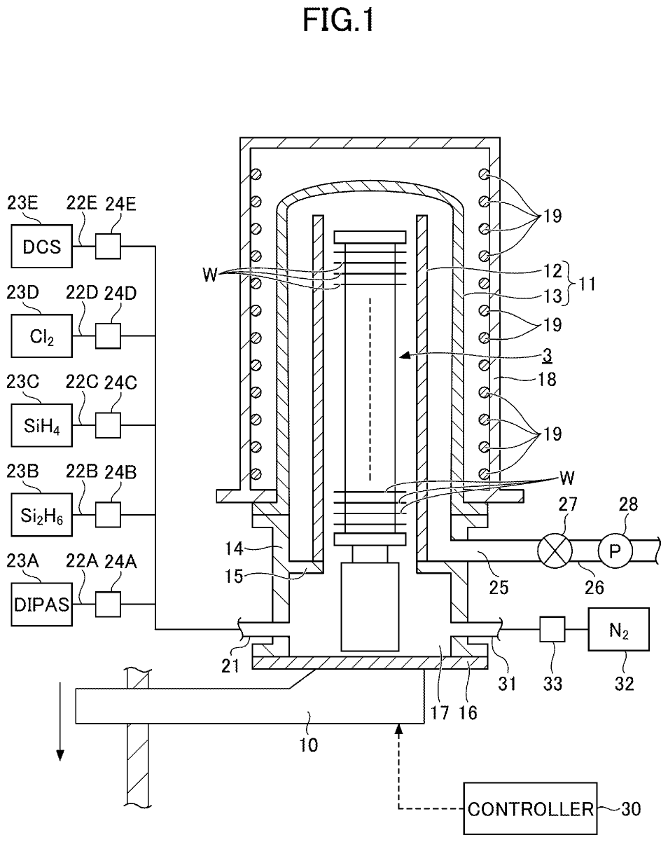

FIG. 1 is a diagram illustrating a substrate processing apparatus according to an embodiment of the present disclosure. In the present embodiment, an example in which the substrate processing apparatus is formed as a vertical heat processing apparatus will be described. Incidentally, the substrate processing apparatus according to the present disclosure is not limited to the vertical heat processing apparatus, but may be applied to a variety of substrate processing apparatuses that can alternately perform film deposition and etching. Applicable substrate processing apparatuses also include a single-wafer substrate processing apparatus and a semi-batch substrate processing apparatus. In the present embodiment, an example in which the substrate processing apparatus is formed as a vertical heat treatment apparatus will be described.

The vertical heat processing apparatus performs a DED process to form a logic device of a semiconductor device in a substrate that is a wafer W. That is, the film deposition process and the etching process are performed on a wafer W. The film deposition process is performed by a thermal CVD (Chemical Vapor Deposition), and the etching process is performed by a reactive gas etching in which thermal energy is supplied to the etching gas.

The logical device to be manufactured includes a logical device using, for example, a FinFET that is the next generation transistor of a MOSFET (Metal Oxide Semiconductor Field Effect Transistor), in addition to the logical device manufactured by conventional art.

The vertical heat processing apparatus includes a reactor tube 11 that is an approximately cylindrical vacuum chamber and the longitudinal direction thereof is oriented to the vertical direction. The reactor tube 11 has a dual tube structure including an inner tube 12, and an outer tube 13 with a ceiling formed so as to cover the inner tube 12 and to have a constant distance from the inner tube 12. The inner tube 12 and the outer tube 13 are formed of a heat resistant material such as quartz. The reactor tube 11 forms a closed space for processing the substrate and may therefore be referred to as a processing chamber.

A manifold 14 made of stainless steel (SUS) formed into a cylindrical shape is disposed below the outer tube 13. The manifold 14 is hermetically connected to the lower end of the outer tube 13. The inner tube 12 protrudes from the inner wall of the manifold 14 and is supported by a support ring 15 integrally formed with the manifold 14.

A lid 16 is disposed below the manifold 14, and a boat elevator 10 allows the lid 16 to be moved up and down between an elevated position and a lowered position. FIG. 1 illustrates the lid 16 located in the elevated position, where the lid 16 closes an opening 17 of the reactor tube 11 below the manifold 14 to seal the inside of the reactor tube 11. The lid 16 includes a wafer boat 3 made of, for example, quartz. The wafer boat 3 is configured to horizontally hold a number of wafers W to be processed as substrates in a stacked manner at a predetermined vertical distance. Around the reactor tube 11, an insulator 18 is disposed to surround the reactor tube 11, and an inner wall thereof has a heater 19 made of a resistance heating element, which is, for example, a heating part, so that the inside of the reactor tube 11 can be heated.

At the manifold 14, below the support ring 15 described above, a process gas inlet tube 21 and a purge gas inlet tube 31 are inserted, and the downstream end of each gas inlet tube 21, 31 is arranged so as to supply a gas to a wafer W within the inner tube 12. For example, the upstream side of the process gas introduction tube 21 branches to form branches 22A to 22E, and each upstream end of the branches 22A to 22E is connected to a supply source 23A of diisopropylaminosilane (DIPAS) gas, a supply source 23B of disilane (Si₂H₆) gas, a supply source 23C of monoaminosilane (SiH₄) gas, a supply source 23D of chlorine (Cl₂) gas, and a supply source 23E of dichlorosilane (SiH₂Cl₂, Dichlorosilane, hereinafter referred to as “DCS”). The branches 22A to 22E include gas supply mechanisms 24A to 24E, respectively. The gas supply mechanisms 24A to 24E each include valves and mass flow controllers configured to control the flow rate of the process gas supplied from the gas supply sources 23A to 23E to the process gas introduction tube 21, respectively.

DIPAS gas is a gas for forming a seed layer to form a first seed layer on a surface of a silicon oxide film formed on a surface of a wafer W, and the gas supply source 23A and the gas supply mechanism 24A constitute a DIPAS gas supply part.

Si₂H₆ gas is a gas for forming a second seed layer on the surface of the first seed layer, and the gas supply source 23B and the gas supply mechanism 24B constitute a Si₂H₆ (disilane) gas supply part.

Also, Si₂H₆ gas may be used as a silicon-containing gas to further deposit an amorphous silicon film on the second seed layer. Details are described below.

DIPAS gas supply part and the disilane gas supply part are gas supply parts for forming the seed layer, and thus may be referred to as a seed layer forming gas supply part.

In the present embodiment, two types of gases for forming the seed layer are described, but any one type of gas for forming the seed layer may be used. In addition, when the film is formed on the wafer W on which the seed layer is already formed, the seed layer forming gas supply part may not be disposed. In addition, gases other than DIPAS gas and Si₂H₆ gas may be used, even if a seed layer forming gas supply part is used. Thus, the DIPAS gas supply part, the disilane gas supply part, and the seed layer forming gas supply part may be provided as necessary.

SiH₄ gas is a deposition gas for depositing a silicon (Si) film on the wafer W on which the seed layer is formed, and the gas supply source 23C and the gas supply mechanism 24C constitute a silicon-containing gas supply part. Because the silicon-containing gas is a gas used for depositing the film, the silicon-containing gas supply part may be referred to as a film deposition gas supply part.

Cl₂ gas is an etching gas for etching the Si film, and the gas supply source 23D and the gas supply mechanism 24D constitute a chlorine gas supply part. Because chlorine gas is supplied as an etching gas, the chlorine gas supply part may be referred to as an etching gas supply part.

DCS gas is a silicon-containing gas for bottom-up deposition, that is, filling of a recess with a silicon film. The gas supply source 23E and the gas supply mechanism 24E constitute a DCS gas supply part. The DCS gas supply part may be referred to as a filling gas supply part, because DCS gas is a gas used for film filling deposition.

The upstream side of the purge gas introduction tube 31 is connected to a supply source 32 of nitrogen (N₂) gas, which is a purge gas. A gas supply mechanism 33 is disposed in the purge gas introduction tube 31. The gas supply mechanism 33 is configured similar to the gas supply mechanisms 24A to 24E to control a flow rate of the purge gas downstream of the introduction tube 31.

In addition, an exhaust port 25 opens in a lateral surface of the support ring 15, and an exhaust gas generated in the inner tube 12 passes through a space formed between the inner tube 12 and the outer tube 13 and is exhausted to the exhaust port 25. An exhaust pipe 26 is hermetically connected to the exhaust port 25. A valve 27 and a vacuum pump 28 are disposed in this order from an upstream side of the exhaust pipe 26. By adjusting the opening of the valve 27, the pressure in the reactor tube 11 is controlled to the desired pressure.

The vertical heat processing apparatus includes a controller 30 that is constituted of a computer, and the controller 30 includes a program. In this program, a group of steps is configured so that a control signal can be output to each part of the vertical heat processing apparatus 1 to control the operation of each part so that a series of processing operations described below can be performed on a wafer W. Specifically, a control signal is output to control the elevation of the lid 16 by the boat elevator 10, the output of the heater 19 (that is, the temperature of the wafer W), the opening of the valve 27, and the flow rate of each gas into the reactor tube 11 by the gas supply mechanisms 24A to 24C, and 33. The program is stored in a storage medium such as a hard disk, a flexible disk, a compact disk, a magneto optical disk (MO), a memory card, or the like in the controller 30.

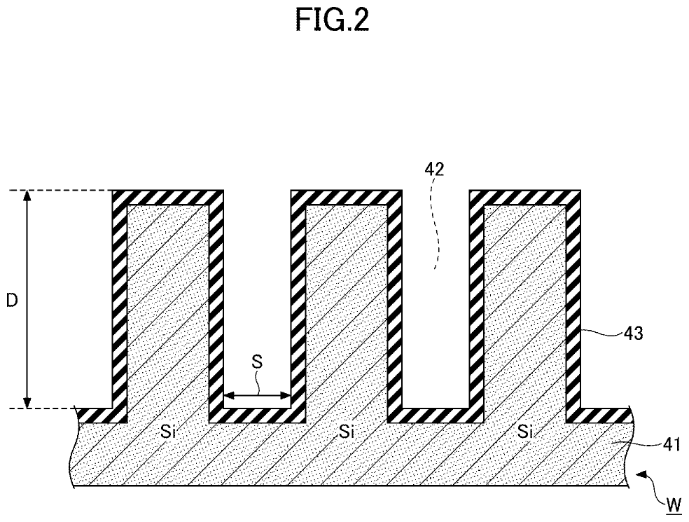

FIG. 2 is a diagram illustrating an example of a shape of a recess formed on a surface of a wafer W. As illustrated in FIG. 2, a silicon (Si) layer 41 is provided on the surface of the wafer W. The surface layer of the Si layer 41 is oxidized and a silicon oxide film 43 is formed. Recesses 42 having a depth D and an opening width S are formed. The recesses 42 are formed, for example, as trenches or through holes, but may have any particular shapes as long as the recesses 42 have depressed shapes.

In FIG. 2, each of the aspect ratios of the recesses 42 is D/S. Each of the aspect ratios of the recesses is, for example, two or more.

First, a general method for filling the recesses 42 with a silicon film by applying a DED process to the recess 42 as illustrated in FIG. 2 will be described.

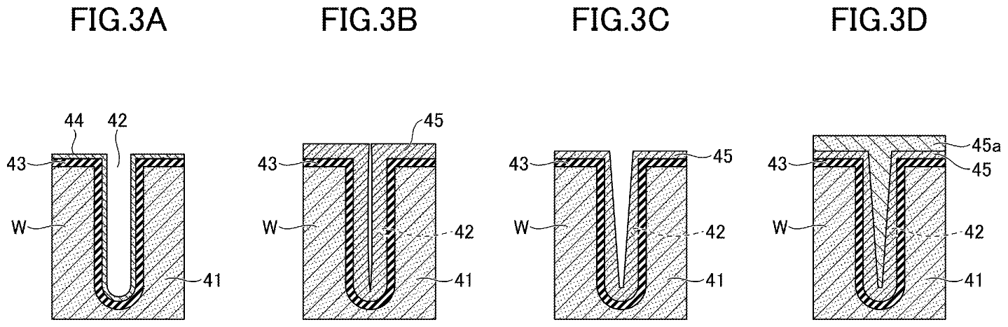

FIGS. 3A to 3D are diagrams illustrating an example of a general and conventional DED process.

FIG. 3A illustrates a seed layer forming step for forming a seed layer 44 on a surface of a wafer W having a recess 42 in a surface. In the seed layer forming step, a thin silicon film is formed as the seed layer 44 on the surface of a silicon oxide film 43 formed on the surface of the wafer W. For the formation of the seed layer 44, for example, Si₂H₆ is used as a film deposition gas.

FIG. 3B illustrates a first film deposition process. In the first film deposition step, for example, SiH₄ gas is used as a film deposition gas, and formed as a layer on the surface of the wafer W, and a silicon film 45 is deposited in the recess 42.

FIG. 3C illustrates an example of an etching process. In the etching process, the deposited silicon film 45 is etched to widen the opening so that the top end is not blocked. Then, a cross-section of the V-shape is formed in the silicon film 45.

FIG. 3D illustrates a second deposition process. In the second film deposition process, a new silicon film 45a is deposited on the V-shaped silicon film 45, and the entire recess 42 is filled with the silicon films 45 and 45a.

While such a filling method is the DED process, high aspect ratio recesses 42 may not have been necessarily filled with the silicon films 45 and 45a by a single DED process, and repeated DED processes have been required to fill the recesses 42. This has caused a problem of requiring a longer process period.

In contrast, a method has been proposed in which SiH₄ and DCS are supplied to a substrate in parallel, and incubation time (a period from the time when supplying a silicon-containing gas to the time when actual film deposition starts) is reset by supplying an etching gas to the silicon oxide film before the incubation time ends.

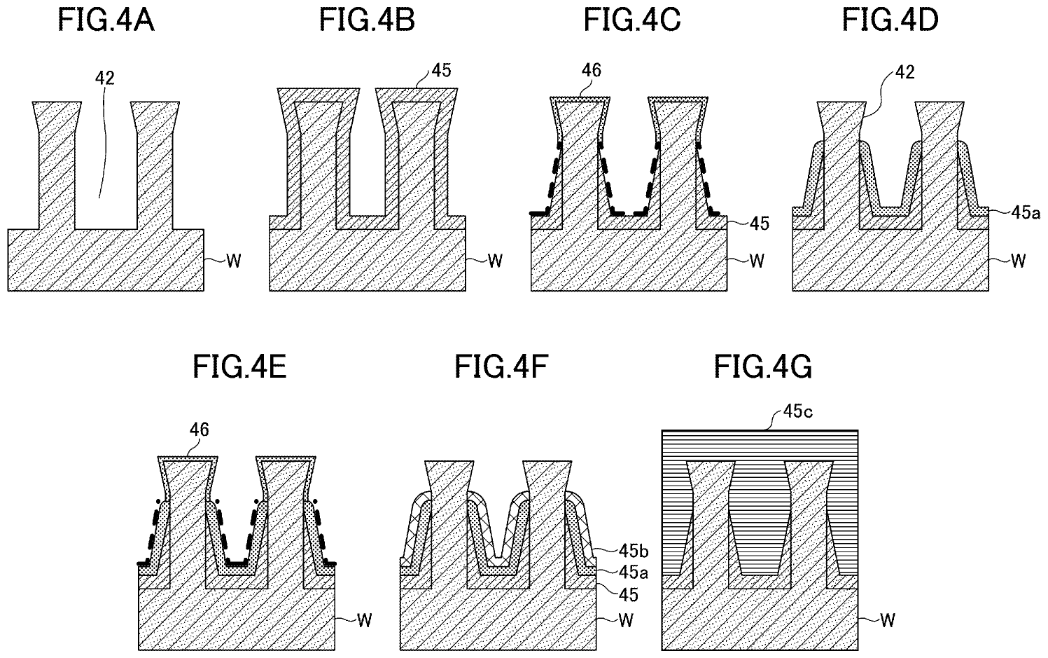

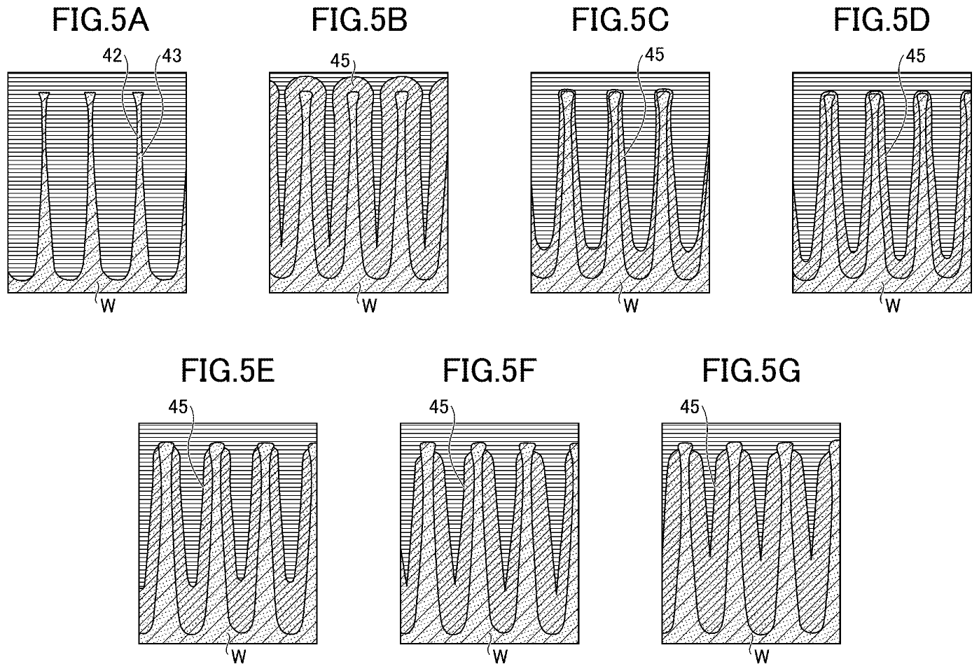

FIGS. 4A to 4G are diagrams illustrating a conventional selective growth method improved relative to the method of FIGS. 3A to 3D. FIGS. 5A to 5G are diagrams based on a TEM image corresponding to FIGS. 4A to 4G. FIGS. 4A to 4G will be mainly described, but actual states can be understood by referring to FIGS. 5A to 5G as appropriate.

FIGS. 4A and 5A are cross-sectional diagrams illustrating a shape of a recess 42 formed on a wafer W. A silicon oxide film 43 is assumed to be formed on a surface of the wafer W, and a seed layer 44 is assumed to be already formed.

FIGS. 4B and 5B are diagrams illustrating a first film deposition step. In the first film deposition steps, a silicon-containing gas (for example, SiH₄ gas) is supplied to the wafer W, and a conformal silicon film 45 is deposited in the recess 42 and on a top surface of the wafer W.

FIGS. 4C and 5C illustrate a first etching step. In the first etching steps, an etching gas (for example, chlorine gas) is supplied to the wafer W to etch the silicon film 45 so that the silicon film 45 remains at the bottom of the recess 42. The etching gas 46 remains on the surface of the wafer W and the silicon film 45.

FIGS. 4D and 5D are diagrams illustrating a second film deposition step. In the second deposition steps, SiH₄ and DCS are supplied to the wafer W, and a new silicon film 45a is further deposited on the silicon film 45.

FIGS. 4E and 5E are diagrams illustrating an etching gas intermittent supplying step. Here, rather than etching the silicon film 45a, an etching gas is supplied to reset incubation time on the silicon film 45a and the wafer W.

FIGS. 4F and 5F illustrate a selective growth step. In the selective growth step, a new silicon film 45b is deposited on the silicon film 45a.

By repeating the cycle consisting of FIGS. 4E and 5E, and FIGS. 4F and 5F, the silicon film 45b selectively grows to form a bottom-up deposited film. This ensures the bottom-up film deposition and allows the recess 42 to be filled with the silicon films 45, 45a, and 45b without generating a void.

FIGS. 4G and 5G illustrate a completion and end stage of a filling step. The recess 42 is filled with the silicon films 45 and 45a to 45c and no void is generated.

Thus, etching gas can be used to reset the incubation time to selectively grow the silicon films 45 and 45a to 45c, and to improve the filling performance in the recess 42. However, due to the repetition of the DE processes, a problem of requiring a long process period has not been solved.

Accordingly, the present disclosure proposes a method for manufacturing a semiconductor device and a substrate processing apparatus that remove the repetition of the DE process and selectively grow a silicon film from the bottom.

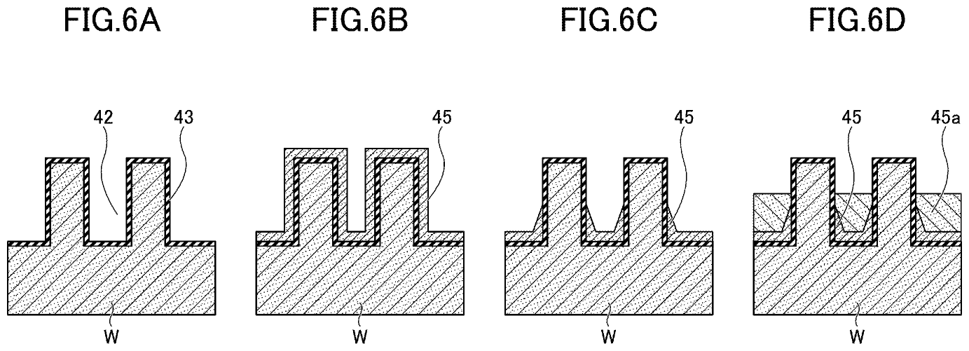

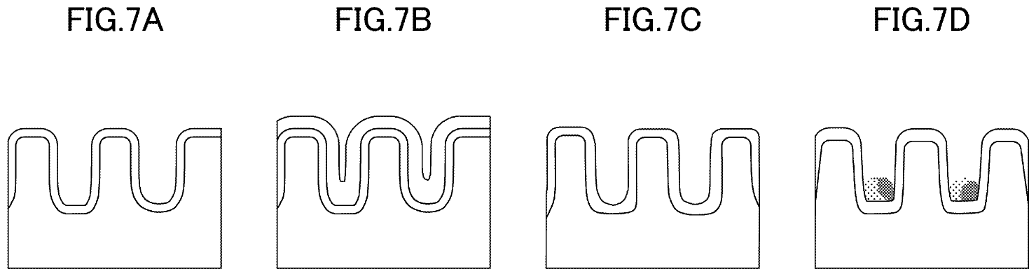

FIGS. 6A to 6D are diagrams illustrating an example of a method for manufacturing a semiconductor device according to an embodiment of the present disclosure. FIGS. 7A to 7D are diagrams based on a TEM image corresponding to FIGS. 6A to 6D for explaining an example of a method for manufacturing a semiconductor device according to an embodiment of the disclosure. An example of a method for manufacturing a semiconductor device according to an embodiment of the present disclosure will be described with reference to FIGS. 6A to 6D, but actual states are shown corresponding to FIGS. 7A to 7D. Also, FIG. 1, which illustrates an apparatus configuration, is referred to, as appropriate.

First, the wafer W described in FIG. 2 is transferred and held in the wafer boat 3 by a transfer mechanism (not illustrated). Thereafter, the wafer boat 3 is placed on the lid 16 that is located at the lowered position. The lid 16 is then raised to the elevated position; the wafer boat 3 is introduced into the reactor tube 11; the lid 16 closes the opening 17 of the reactor tube 11, and the inside of the reactor tube 11 is made airtight. Subsequently, a purge gas is supplied into the reactor tube 11; the inside of the reactor tube 11 is evacuated to a vacuum atmosphere of a predetermined pressure; and the wafer W is heated by the heater 19 to a predetermined temperature. The temperature is set to a predetermined deposition temperature suitable for depositing a silicon film on the wafer W. The controller 30 may control the temperature of the heater 19.

For example, SiH₄ gas may be in the range of 440 degrees C. to 530 degrees C. when used as a film deposition gas.

FIGS. 6A and 7A illustrate an example of a seed layer forming step.

After the wafer W is heated, the purge gas supply is stopped and DIPAS gas is supplied into the reactor tube 11. DIPAS gas is deposited on the surface of the silicon oxide film 43 of the wafer W, and a first seed layer 44 is formed so as to coat the silicon oxide film 43 (not illustrated).

Thereafter, the DIPAS gas supply is stopped; the purge gas is supplied to the reactor tube 11; DIPAS gas is purged from the reactor tube 11; and Si₂H₆ gas is supplied to the reactor tube 11. Si₂H₆ gas is deposited on the first seed layer, and a second seed layer is formed to coat the first seed layer. Thereafter, the Si₂H₆ gas supply is stopped and the purge gas is supplied to the reactor tube 11 to purge Si₂H₆ gas from the reactor tube 11.

FIGS. 6B and 7B illustrate an example of a first film deposition step.

After the seed layer forming step, the purge gas supply is stopped and SiH₄ gas is supplied into the reactor tube 11. As illustrated in FIG. 6B, SiH₄ gas is deposited on the second seed layer and formed over the whole surface of the wafer W so that the Si film 44 covers the second seed layer. Then, SiH₄ gas continues to be deposited and the Si film 45 grows. That is, the thickness of the Si film 45 increases. Then, for example, as illustrated in FIG. 6B, the SiH₄ gas supply stops before the upper side of the recess 42a is blocked by the Si film 45. At this stage, the recess 42b has a very narrow gap from opposing sides of the silicon film 45.

In the first film deposition step, the silicon film 45 is preferably deposited so that the gap from opposing sides of the silicon film 45 is as narrow as possible as long as the opposing sides of the silicon film 45 do not contact each other. In the next etching step, in order to perform etching while leaving the silicon film 45 on the bottom of the recess 42, the etching is preferably performed so that the etching gas does not easily reach the bottom of the recess 42. Incidentally, the gap of the opposing sides of the silicon films 45 is, for example, 10 nm to 100 nm.

Here, Si₂H₆ gas may be used instead of SiH₂ gas. In this case, the first film deposition step may be carried out consecutively from the seed layer forming step.

In the first film deposition step, an amorphous silicon film 45 is formed on the inner surface of the recess 42 and on the top surface of the wafer W.

After the SiH₄ gas supply or Si₂H₆ gas supply is stopped, a purge gas is supplied into the reactor tube 11, and SiH₄ gas or Si₂H₆ gas is purged from the reactor tube 11.

FIGS. 6C and 7C illustrate an example of a first etching step. In the first etching step, Cl₂ gas is supplied to the process gas introduction tube 21 from the gas supply source 23D and is supplied to a wafer W in the reactor tube 11 (see FIG. 1).

Cl₂ gas is an etching gas for the silicon film 45, and produces active species such as Cl radicals by being heated and receiving thermal energy in the reactor tube 11. Because the active species are relatively reactive to Si, the active species react with Si outside the recess 42 and on the upper side of the recess 42, and produce SiCl₄ (silicon tetrachloride) and etch the silicon film 45 until the active species reach the lower part in the recess 42 of the wafer W. Accordingly, etching is performed so that the decrease in thickness of the upper-side Si film 45 within the recess 42 is greater than the decrease in thickness of the lower-side Si film 45 within the recess 42, thereby increasing the opening width on the upper side within the recess 42. One mole of Cl₂ produces two moles of Cl radicals. In other words, because relatively many active species are generated, expanding the opening width of the recess can proceed at a relatively high rate.

On this occasion, the etching gas is supplied under the supply limited mode conditions such that the silicon film 45 remains on the bottom of the recess 42. Specifically, the flow rate and/or concentration of the etching gas is controlled so that the silicon film 45 remains only on the bottom. That is, etching removes the silicon film 45 and the seed layer 44 from the upper portion of the recess 42 and the top surface of the wafer W, and exposes the silicon oxide film 43, but the etching gas is supplied so that the silicon film 45 remains on the bottom of the recess 42. Ideally, the silicon film 45 is completely removed from the upper portion of the recess 42 and the top surface of the wafer W, and the silicon film 45 remains only on the bottom of the recess 42. However, even if some silicon film 45 remains on the upper portion of the recess 42 and on the top surface of the wafer, as long as the surrounding silicon oxide film 43 is exposed, the process will not be significantly affected. However, because the silicon film may be grown therefrom, the silicon film 45 and the seed layer 44 are preferably removed as completely as possible except for those on the bottom and the lower portion of the recess 42.

Incidentally, in order to set the etching gas to the supply limited mode, for example, the temperature is set to be 250 degrees C. or more.

FIGS. 6D and 7D are diagrams illustrating an example of a second film deposition process. In the second film deposition step, DCS gas is supplied from the dichlorosilane gas supply source 23E, and a new silicon film 45a is deposited on the etched silicon film 45. On this occasion, because the amorphous silicon film 45 is present only on the bottom of the recess 42a, the silicon film 45a selectively grows upward. That is, the silicon film 45a grows from the bottom, and fills the recess 42. Because of bottom-up growth, the silicon film 45a fills the recess 42 without any void.

Thereafter, the second film deposition step is continued and the silicon film 45a fills the recess 42. The silicon film 45a is a polysilicon film. Thus, the polysilicon film 45a selectively grows in the recess 42 without generating a void.

Once all recesses 42a have been filled with a silicon film, the temperature in the reactor tube 11 is lowered. During the process, the temperature is maintained at a constant deposition temperature, but when the process is completed, the temperature in the reactor tube 11 is decreased to take out the wafer W. This causes the wafer W to cool down.

Subsequently, after the lid 16 is lowered and the wafer boat 3 is unloaded from the reactor tube 11, the wafer W is removed from the wafer boat 3 by a transport mechanism (not illustrated) and one batch of a wafer W process is completed. Because the processing temperature can be kept constant during the process, the filling process can be performed in a short time.

Thus, according to the method for manufacturing the semiconductor device according to the present embodiment, the polysilicon film can be selectively grown in the recess 42 by etching the amorphous silicon film 45 so as to leave the amorphous silicon film 45 on the bottom of the recess 42 during the etching process, and the recess 42 can be filled with a silicon film without generating a void.

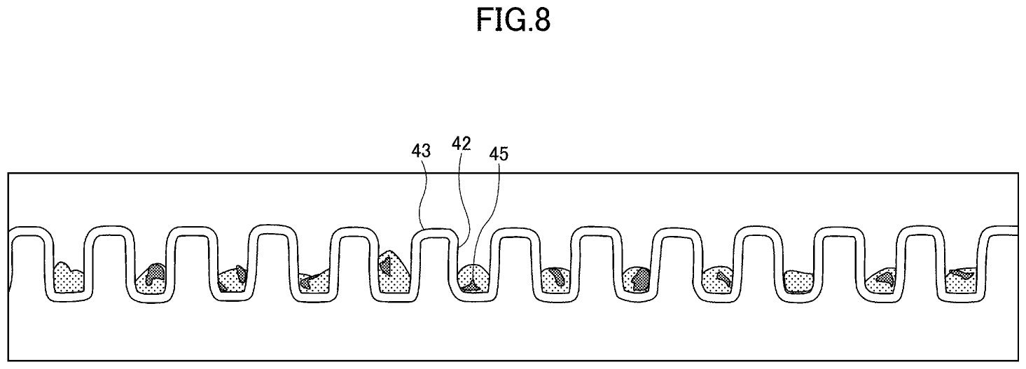

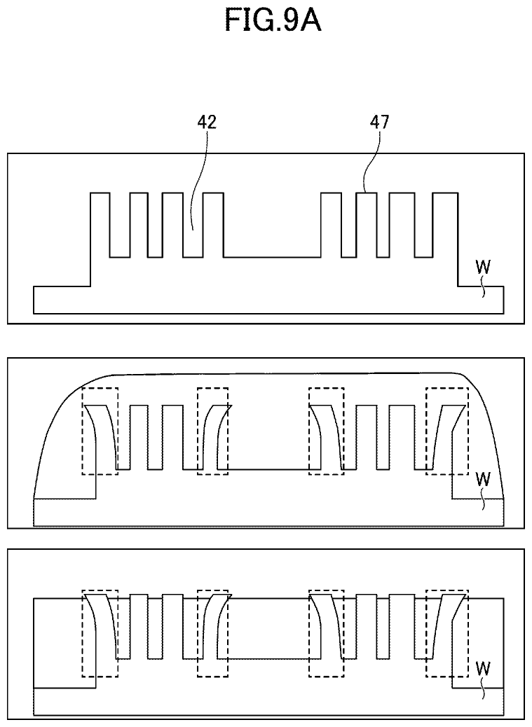

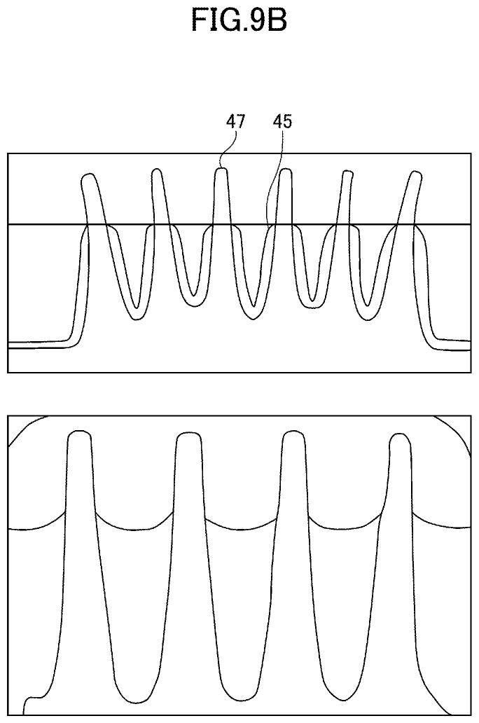

FIG. 8 is a diagram based on a TEM image showing a result of performing a method of manufacturing a semiconductor device according to the present embodiment. FIG. 8 illustrates a state of a silicon film 45a deposited on the bottom of the recess 42, and an exposed silicon oxide film 43 on the upper portion of the recess 42 and the top surface of the wafer W. Thus, FIG. 8 shows a method for manufacturing a semiconductor device according to the embodiment can implement the bottom-up growth.

FIGS. 9A and 9B are diagrams illustrating a problem with a conventional semiconductor device manufacturing method. FIG. 9A is a diagram showing an occurrence state of fin bending. FIG. 9B is a more detailed diagram of an occurrence of fin bending.

As shown in FIGS. 9A and 9B, a silicon film 45 is deposited on a side wall of a recess 42 or on a lateral surface of a fin 47, and when there is a difference in thickness between the left and right films, fin bending occurs in which the fins 47 bend. This occurs most often when the film is deposited and annealed. If the silicon film 45 is deposited on the sidewalls without selective growth from the bottom of the recess 42, stress is generated by the contraction of the silicon film 45 when heated. Here, there is no problem if the amount of silicon film 45 deposited on the right and left side walls is equal, but if the amount of silicon film 45 deposited on the right and left sides is different, there is a problem that the difference in the right and left stresses occurs and the fins 47 bend due to an imbalance in the stress from the left and the right sides.

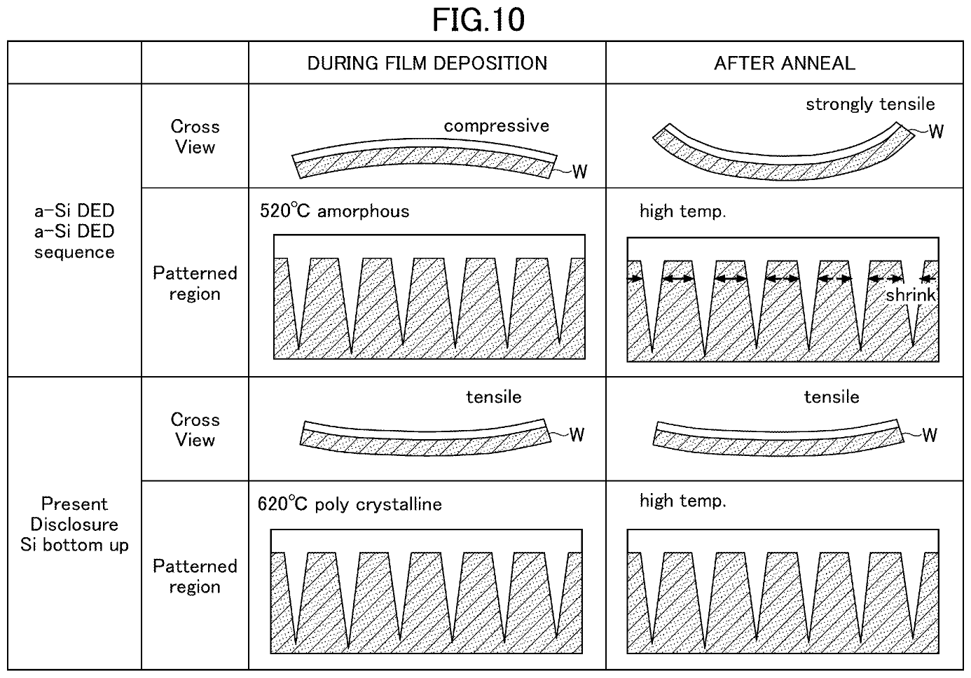

FIG. 10 is a diagram comparing a state of a fin of a semiconductor device manufactured by a method for manufacturing a semiconductor device according to the present embodiment to a conventional DED process described in FIGS. 4A to 4G and 5A to 5G.

In FIG. 10, the top row shows a state of fins in a conventional DED process and the bottom row shows a state of fins in a method for manufacturing a semiconductor device according to the present embodiment. In addition, the left side shows a state when a film is deposited, and the right side shows a state after annealing.

As shown in the left column of FIG. 10, there is no significant difference in the degree of bending of the wafer W between the conventional DED process and the method for manufacturing the semiconductor device according to the present embodiment during film deposition. However, in a conventional DED process, silicon films are deposited in an amorphous state, whereas in the method for manufacturing a semiconductor device according to the present embodiment, silicon films are deposited in a polysilicon state, where crystallization is completed.

As the right column indicates, the wafer W is greatly bent in the conventional DED process after annealing, but in the method for manufacturing the semiconductor device according to the present embodiment, the bending degree is not appreciably changed compared to the time of film deposition.

This is because, when heated at a high temperature, the silicon film of the conventional DED process is deposited in the amorphous state, causing the silicon film to shrink greatly due to the loss of hydrogen. In contrast, because the silicon film manufactured by the method for manufacturing the semiconductor device according to the present embodiment is a polysilicon film and the silicon film is crystallized, the state of the silicon film does not change when heated, and the wafer W is not bent.

As described above, according to the method for manufacturing the semiconductor device and the substrate processing apparatus according to the present embodiment, a high quality silicon film without causing fin bending can fill a recess without generating a void in the recess.

According to the present embodiment, the recess can be filled with a silicon film without repeating a DED process.

All examples recited herein are intended for pedagogical purposes to aid the reader in understanding the disclosure and the concepts contributed by the inventor to furthering the art, and are to be construed as being without limitation to such specifically recited examples and conditions, nor does the organization of such examples in the specification relate to a showing of the superiority or inferiority of the disclosure. Although the embodiments of the present disclosure have been described in detail, it should be understood that various changes, substitutions, and alterations could be made hereto without departing from the spirit and scope of the disclosure.

What is claimed is:

1. A method for manufacturing a semiconductor device, the method comprising:
depositing an amorphous silicon film in a recess provided in a surface of a substrate by supplying a silicon-containing gas to the substrate;
etching the amorphous silicon film by supplying an etching gas to the substrate so as to leave the amorphous silicon film on a bottom of the recess; and
depositing a silicon film on the amorphous silicon film by supplying dichlorosilane to the substrate.

2. The method as claimed in claim 1, wherein the surface of the recess is covered with an oxide film, and the step of etching the amorphous silicon film comprises exposing the oxide film on the surface of the recess other than the oxide film on the bottom of the recess.

3. The method as claimed in claim 2, wherein the oxide film is a silicon dioxide film.

4. The method as claimed in claim 1, wherein the step of etching the amorphous silicon film is performed by supplying the etching gas in a supply limited mode so as not to completely etch the amorphous silicon film up to the bottom surface of the recess.

5. The method as claimed in claim 4, wherein the supply limited mode is performed by controlling at least one of a flow rate and a concentration of the etching gas.

6. The method as claimed in claim 4, wherein the etching gas is chlorine.

7. The method as claimed in claim 1, wherein the step of depositing the amorphous silicon film in the recess comprises supplying monosilane or disilane.

8. The method as claimed in claim 1, wherein the step of depositing the amorphous silicon film in the recess comprises depositing the amorphous silicon film in the recess such that a width of an opening formed by opposing sides of the amorphous silicon film is formed so as to hinder the etching gas from passing the opening in a range of not blocking the opening formed by the opposing sides of the amorphous silicon film.

9. The method as claimed in claim 1, wherein the silicon film deposited on the amorphous silicon film is a polysilicon film.

10. The method as claimed in claim 1, wherein depositing the silicon film on the amorphous silicon film is performed until the silicon film fills the recess.

11. A substrate processing apparatus, comprising:
a processing chamber;
a substrate holding member disposed in the processing chamber and configured to hold a substrate having a recess in a surface of the substrate;
a silicon-containing gas supply part configured to supply a silicon-containing gas and to deposit an amorphous silicon film in the recess;
an etching gas supply part configured to supply an etching gas to the substrate so as to leave the amorphous silicon film on a bottom of the recess; and
a dichlorosilane supply part configured to supply a dichlorosilane to the substrate and to deposit a silicon film on the amorphous silicon film.
